(19) United States
(12) Patent Application Publication
(10) Pub. No.: US 2025/0125212 A1
(43) Pub. Date: Apr. 17, 2025

(54) Integrated Circuit with a Metal Thin Film

(71) Applicants: Chih-Hsiang Lin, Taoyuan City (TW); Chin-Cheng Lo, Hsinchu County (TW)

(72) Inventors: Chih-Hsiang Lin, Taoyuan City (TW); Chin-Cheng Lo, Hsinchu County (TW)

(21) Appl. No.: 18/824,416

(22) Filed: Sep. 4, 2024

(30) Foreign Application Priority Data
Oct. 11, 2023 (TW) 112210877

(51) Int. Cl. H01L 23/367; H01L 23/552

(52) U.S. Cl. CPC H01L 23/3675; H01L 23/552

(57) ABSTRACT

An integrated circuit with a metal thin film includes: a packaging shell with a top surface, a plurality of side surfaces and a bottom surface. The side surfaces each have one end connected to the top surface and the other surface connected to the bottom surface. The bottom surface includes a plurality of metal pins; and a metal thin film layer coated on the top surface, or at least one of the side surfaces, or both the top surface and at least one of the side surfaces.

### BACKGROUND

### Field of the Invention

The present invention relates to an integrated circuit, and more particularly to an integrated circuit with a metal thin film.

### Description of Related Art

Electronic components and integrated circuits often use heat dissipation fins for heat dissipation. Therefore, heat dissipation fins are an extremely important part of circuit design. The heat generated by the electronic components, such as bipolar junction transistors (BJTs) and metal oxide semiconductor field effect transistors (MOSFETs), can be dissipated into the surrounding air through heat dissipation fins to ensure that electronic components are not damaged due to high temperatures.

For a general integrated circuit with heat dissipation fins installed, as shown in FIG. 1, a Thermal Interface Material (TIM) 60 is coated on the top of the shell 50 of the integrated circuit, and a heat dissipation fin 70 is installed on the TIM 60. However, the thermal resistance designed above includes the thermal resistance RΘjc from the bare crystal interface 40 of the integrated circuit to the shell 50, the thermal resistance RΘct from the shell 50 to the TIM 60, the thermal resistance RΘts from the TIM 60 to the heat dissipation fin 70, and the thermal resistance RΘsa from the heat dissipation fin 70 to the surrounding environment, resulting in a total thermal resistance value that is still too high.

In addition, the above-mentioned technology solution using heat dissipation fins is also prone to increasing the volume and manufacturing cost of the product, which goes against the design trend of lightweight, thin, short, and small integrated circuits.

Therefore, a low thermal resistance, small volume, and low manufacturing cost integrated circuit is needed.

### SUMMARY

The present invention provides an integrated circuit with metal thin film, an objective of which is to provide an integrated circuit with low thermal resistance and small volume.

Another objective of the present invention is to make the integrated circuit have an effect of electromagnetic barrier.

To achieve the above objectives, the present invention provides an integrated circuit with a metal thin film, which comprises:
a packaging shell including a top surface, a plurality of side surfaces, and a bottom surface, wherein the side surfaces each have one end connected to the top surface, and another end connected to the bottom surface, the bottom surface includes a plurality of metal pins; and
a metal thin film layer is coated on the top surface or at least one of the side surfaces or on both the top surface and at least one of the side surfaces.

Preferably, the metal thin film layer has a thickness ranging from 150 to 200 nm.

The thermal resistance of the integrated circuit with metal thin film in accordance with the present invention can be regarded as only the thermal resistance from the bare chip junction to the packaging shell. Therefore, the present invention has the advantage of low thermal resistance, and the thickness of the metal thin film layer in the present invention is between 150-200 nm, and the thickness of the conventional heat dissipation fin can be omitted to achieve the goal of small volume.

In addition, due to the presence of the metal thin film layer on the top surface or the side surfaces, or both the top surface and the side surfaces of the packaging shell, the metal thin film not only prevents external signal interference, but also prevents internal electromagnetic fields from leaking to the outside.

### BRIEF DESCRIPTION OF THE DRAWINGS

FIG. 1 is an illustrative view of a conventional integrated circuit with heat dissipation fins;

FIG. 2 is an illustrative view showing conventional thermal resistance using heat dissipation fins for heat dissipation;

FIG. 3 is an illustrative view of the integrated circuit with a metal fin film in accordance with the present invention; and

FIG. 4 is an illustrative view showing thermal resistance of the integrated circuit with a metal fin film in accordance with the present invention.

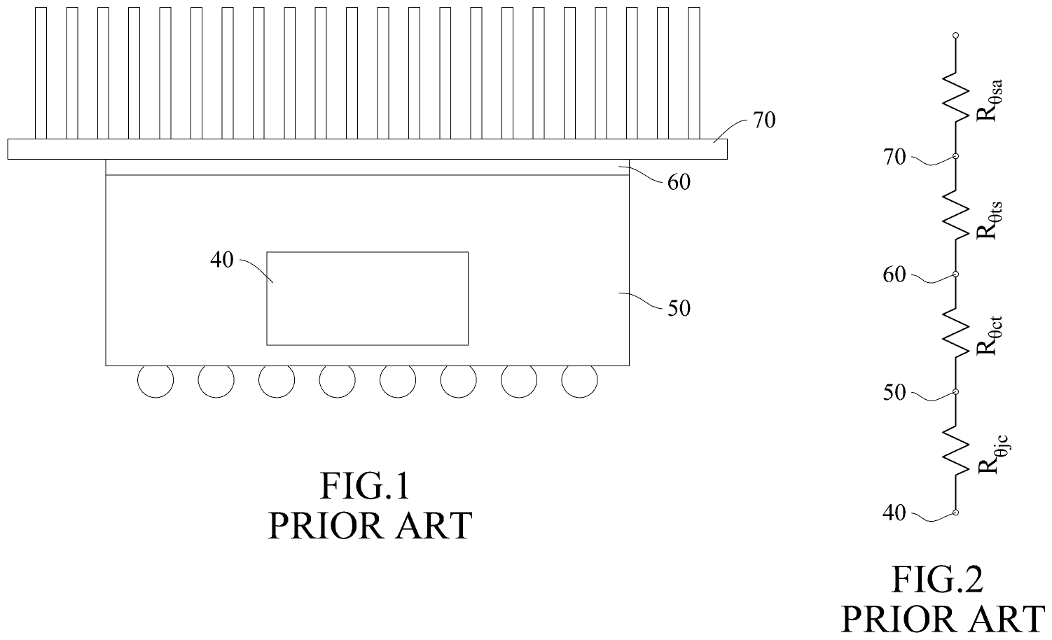

### DETAILED DESCRIPTION

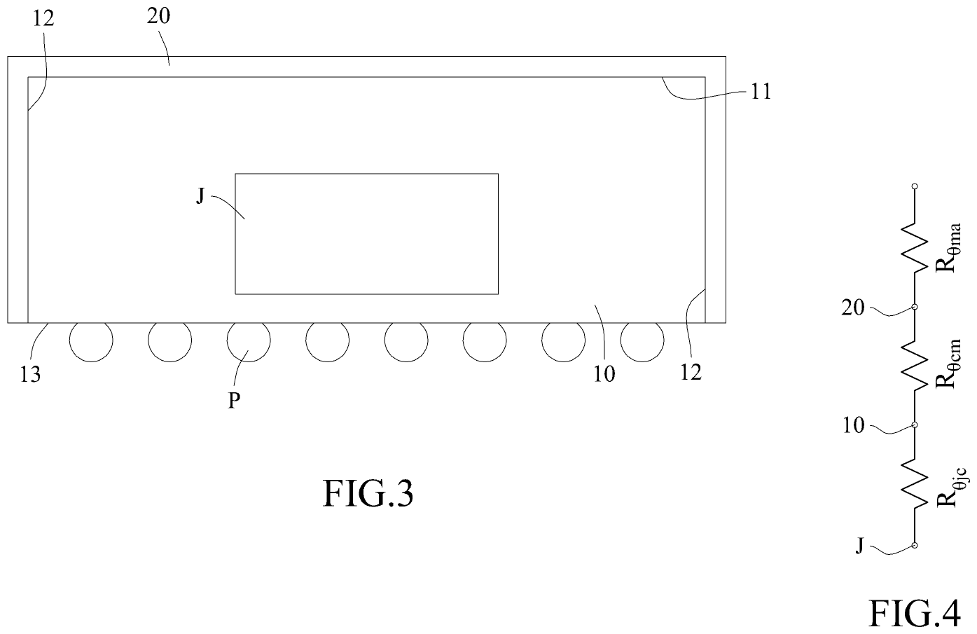

The present invention provides an integrated circuit with a metal thin film, as shown in FIGS. 3-4, including:

A packaging shell 10 has a top surface 11, a plurality of side surfaces 12, and a bottom surface 13. The side surfaces 12 each have one end connected to the top surface 11, and the other end connected to the bottom surface 13. The bottom surface 13 includes a plurality of metal pins P soldered to a printed circuit board (PCB). In this embodiment, the packaging shell 10 is rectangular or square, and the number of the side surfaces 12 is four.

A metal thin film layer 20 is coated on the top surface 11 or at least one of the side surfaces 12 or on both the top surface 11 and at least one of the side surfaces 12. In this embodiment, the metal thin film layer 20 is coated on the top surface 11 and four of the side surfaces 12. The thickness of the metal thin film layer 20 is between 150-200 nm, and the material of the metal thin film layer 20 can be selected from metals with high thermal conductivity such as silver, copper, gold, aluminum, etc., but is not limited thereto.

Preferably, the metal thin film layer 20 is coated on the top surface 11 or the side surfaces 12, or both the top surface 11 and the side surfaces 12 of the packaging shell 10 through a vacuum evaporation process.

Thus, the thermal resistance of the integrated circuit with metal thin film in accordance with the present invention includes: the thermal resistance RΘjc from the bare chip junction J to the packaging shell 10, the thermal resistance RΘcm from the packaging shell 10 to the metal thin film layer 20, and the thermal resistance RΘma from the metal thin film layer 20 to the surrounding environment.

The thermal resistance RΘcm from the packaging shell 10 to the metal thin film layer 20 is:

$$R Θ cm = \frac{{T}_{1} - {T}_{2}}{{P}_{d}} ( ° C / W ) .$$

Due to the high thermal conductivity of the metal thin film layer 20 and its thickness ranging from 150 to 200 nm, the thermal resistance RΘcm from the packaging shell 10 to the metal thin film layer 20 is extremely small and almost negligible.

The thermal resistance of the metal thin film layer 20 to the surrounding environment is:

$$R Θ ma = \frac{{T}_{1} - {T}_{2}}{{P}_{d}} ( ° C / W ) .$$

T1 is the temperature at one end of the metal thin film layer 20, T2 is the temperature at the other end of the metal thin film layer 20, and Pd is the conduction and switching losses of the component. Due to the thickness of the metal thin film layer 20 ranging from 150 to 200 nm, the temperature T1 at one end of the metal thin film layer 20 is very close to the temperature T2 at the other end of the metal thin film layer 20. Therefore, the thermal resistance RΘma of the metal thin film layer 20 to the surrounding environment is also almost negligible.

In summary, the thermal resistance of the integrated circuit with metal thin film in accordance with the present invention can be regarded as only the thermal resistance RΘjc from the bare chip junction J to the packaging shell 10. Therefore, the present invention has the advantage of low thermal resistance, and the thickness of the metal thin film layer 20 in the present invention is between 150-200 nm, and the thickness of the conventional heat dissipation fin can be omitted to achieve the goal of small volume.

In addition, due to the presence of the metal thin film layer 20 on the top surface 11 or the side surfaces 12, or both the top surface 11 and the side surfaces 12 of the packaging shell 10, the metal thin film layer 20 can block external electromagnetic waves.

What is claimed is:

1. An integrated circuit with a metal thin film, comprising:
a packaging shell including a top surface, a plurality of side surfaces, and a bottom surface, wherein the side surfaces each have one end connected to the top surface, and another end connected to the bottom surface, the bottom surface includes a plurality of metal pins; and
a metal thin film layer is coated on the top surface or at least one of the side surfaces or on both the top surface and at least one of the side surfaces.

2. The integrated circuit with the metal thin film as claimed in claim 1, wherein the packaging shell is rectangular or square, the number of the side surfaces is four, and the metal thin film layer is coated on the top surface and four of the side surfaces.

3. The integrated circuit with the metal thin film as claimed in claim 1, wherein the metal thin film layer has a thickness ranging from 150 to 200 nm.

4. The integrated circuit with the metal thin film as claimed in claim 1, wherein a material of the metal thin film layer is selected from a group consisting of silver, copper, gold and aluminum.
